(19) United States
(12) Patent Application Publication
(10) Pub. No.: US 2025/0017085 A1
(43) Pub. Date: Jan. 9, 2025

(54) DISPLAY DEVICE AND MANUFACTURING METHOD THEREOF

(71) Applicant: Japan Display Inc., Tokyo (JP)

(72) Inventors: Ze YUAN, Tokyo (JP); Hidekazu MIYAKE, Tokyo (JP)

(73) Assignee: Japan Display Inc., Tokyo (JP)

(21) Appl. No.: 18/754,199

(22) Filed: Jun. 26, 2024

(30) Foreign Application Priority Data
Jul. 3, 2023 (JP) 2023-109459

(51) Int. Cl. H10K 59/80; H10K 59/12

(52) U.S. Cl. CPC H10K 59/879; H10K 59/1201

(57) ABSTRACT

According to one embodiment, a display device includes a lower electrode, an organic layer, an upper electrode, an insulating layer, a color filter having a first surface which faces the insulating layer, and a second surface on a side opposite to the first surface, a first lens provided on the first surface immediately above the lower electrode, formed into a convex shape and covered with the insulating layer, and a second lens provided on the second surface immediately above the lower electrode and formed into a convex shape. The second lens comprises at least a first layer having a first refractive index and formed into a hemispherical shape, and a second layer having a second refractive index higher than the first refractive index and covering the first layer.

### CROSS-REFERENCE TO RELATED APPLICATION

This application is based upon and claims the benefit of priority from Japanese Patent Application No. 2023-109459, filed Jul. 3, 2023, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a lower electrode, an upper electrode which faces the lower electrode, and an organic layer located between the lower electrode and the upper electrode and including a light emitting layer.

In the display element described above, a technique which efficiently extracts the light generated in the light emitting layer to the outside is required. For example, a technique which applies an inner extraction layer formed on the inner surface of a substrate facing the display element and an outer extraction layer formed on the outer surface of the substrate is known.

### BRIEF DESCRIPTION OF THE DRAWINGS

FIG. 1 is a diagram showing a configuration example of a display device.

FIG. 2 is a diagram showing a configuration example of subpixels SP1, SP2 and SP3.

FIG. 3 is a diagram showing an example of the layout of subpixels SP1, SP2 and SP3.

FIG. 4 is a diagram showing an example of the layout of color filters CF1, CF2 and CF3, first lenses LS1 and second lenses LS2.

FIG. 5 is a cross-sectional view showing a configuration example of the display device DSP along the A-B line of FIG. 4.

FIG. 6 is a diagram for explaining the effect of the first lens LS1.

FIG. 7 is a diagram for explaining the effect of the second lens LS2.

FIG. 8 is a diagram for explaining the manufacturing method of the first lenses LS1 and a color filter CF.

FIG. 9 is a diagram for explaining the manufacturing method of the second lenses LS2.

FIG. 10 is a diagram showing another example of the layout of the first lenses LS1 and the second lenses LS2.

FIG. 11 is a diagram showing another example of the layout of the first lenses LS1 and the second lenses LS2.

FIG. 12 is a diagram showing another example of the layout of the first lenses LS1 and the second lenses LS2.

FIG. 13 is a diagram showing another example of the layout of the first lenses LS1 and the second lenses LS2.

### DETAILED DESCRIPTION

Embodiments described herein aim to provide a display device in which the light extraction efficiency is improved and the viewing angle can be broadened, and a manufacturing method thereof.

In general, according to one embodiment, a display device comprises a substrate, a lower electrode provided above the substrate, an organic layer provided on the lower electrode and including a light emitting layer, an upper electrode provided on the organic layer, an insulating layer provided above the upper electrode, a color filter having a first surface which faces the insulating layer, and a second surface on a side opposite to the first surface, a first lens provided on the first surface immediately above the lower electrode, formed into a convex shape and covered with the insulating layer, and a second lens provided on the second surface immediately above the lower electrode and formed into a convex shape. The second lens comprises at least a first layer having a first refractive index and formed into a hemispherical shape, and a second layer having a second refractive index higher than the first refractive index and covering the first layer.

According to another embodiment, a manufacturing method of a display device comprises forming an insulating layer above a display element by using an organic material, forming a patterned resist on the insulating layer, forming a recess portion by removing part of the insulating layer using the resist as a mask, forming a first lens with which the recess portion is filled, forming a color filter on the first lens, and forming a second lens having a convex shape on the color filter. The forming the second lens includes at least forming a hemispherical first layer by using a material having a first refractive index, and forming a second layer which covers the first layer by using a material having a second refractive index higher than the first refractive index.

The embodiments can provide a display device in which the light extraction efficiency is improved and the viewing angle can be broadened, and a manufacturing method thereof.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various types of elements are viewed parallel to the third direction z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the present embodiment is an organic electroluminescent (EL) display device comprising an organic light emitting diode (OLED) as a display element, and could be mounted on a television, a personal computer, a vehicle-mounted device, a tablet, a smartphone, a mobile phone, etc.

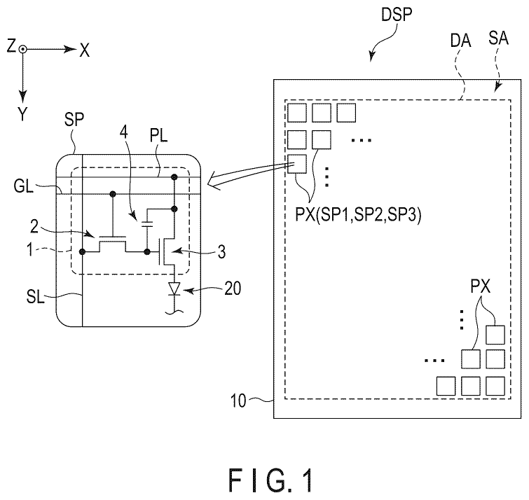

FIG. 1 is a diagram showing a configuration example of a display device DSP.

The display device DSP comprises a display area DA which displays an image and a surrounding area SA around the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4 etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Although not described in detail, a terminal for connecting an IC chip and a flexible printed circuit is provided in the surrounding area SA.

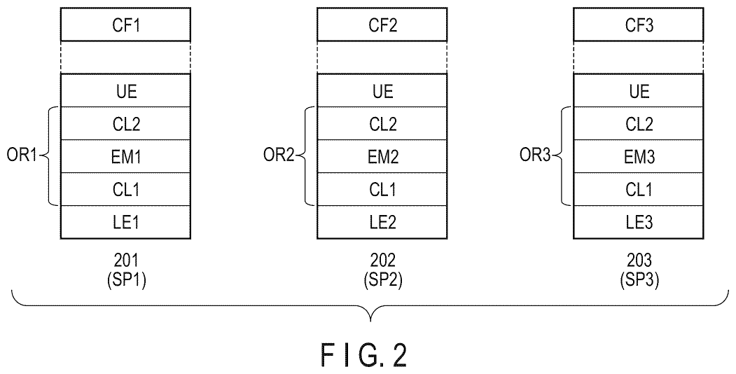

FIG. 2 is a diagram showing a configuration example of subpixels SP1, SP2 and SP3.

Subpixels SP1, SP2 and SP3 comprise display elements 201, 202 and 203, respectively, as the display elements 20. Subpixel SP1 comprises a color filter CF1 facing the display element 201. Subpixel SP2 comprises a color filter CF2 facing the display element 202. Subpixel SP3 comprises a color filter CF3 facing the display element 203.

The display element 201 comprises a lower electrode LE1, an organic layer OR1 including a light emitting layer EM1, and an upper electrode UE. The organic layer OR1 is provided between the lower electrode LE1 and the upper electrode UE. The light emitting layer EM1 is formed of a material which emits light exhibiting the first color. The color filter CF1 is colored in the first color.

The display element 202 comprises a lower electrode LE2, an organic layer OR2 including a light emitting layer EM2, and the upper electrode UE. The organic layer OR2 is provided between the lower electrode LE2 and the upper electrode UE. The light emitting layer EM2 is formed of a material which emits light exhibiting the second color. The color filter CF2 is colored in the second color.

The display element 203 comprises a lower electrode LE3, an organic layer OR3 including a light emitting layer EM3, and the upper electrode UE. The organic layer OR3 is provided between the lower electrode LE3 and the upper electrode UE. The light emitting layer EM3 is formed of a material which emits light exhibiting the third color. The color filter CF3 is colored in the third color.

For example, the lower electrodes LE1, LE2 and LE3 correspond to the anodes of the display elements, and the upper electrode UE corresponds to the cathodes of the display elements or a common electrode.

In the example shown in the figure, each of the organic layers OR1, OR2 and OR3 includes a common layer CL1 and a common layer CL2.

The common layer CL1 has, for example, a hole injection layer, a hole transport layer and an electron blocking layer. The common layer CL1 is provided between the lower electrode LE1 and the light emitting layer EM1, between the lower electrode LE2 and the light emitting layer EM2 and between the lower electrode LE3 and the light emitting layer EM3.

The common layer CL2 has, for example, an electron injection layer, an electron transport layer and a hole blocking layer. The common layer CL2 is provided between the light emitting layer EM1 and the upper electrode UE, between the light emitting layer EM2 and the upper electrode UE and between the light emitting layer EM3 and the upper electrode UE.

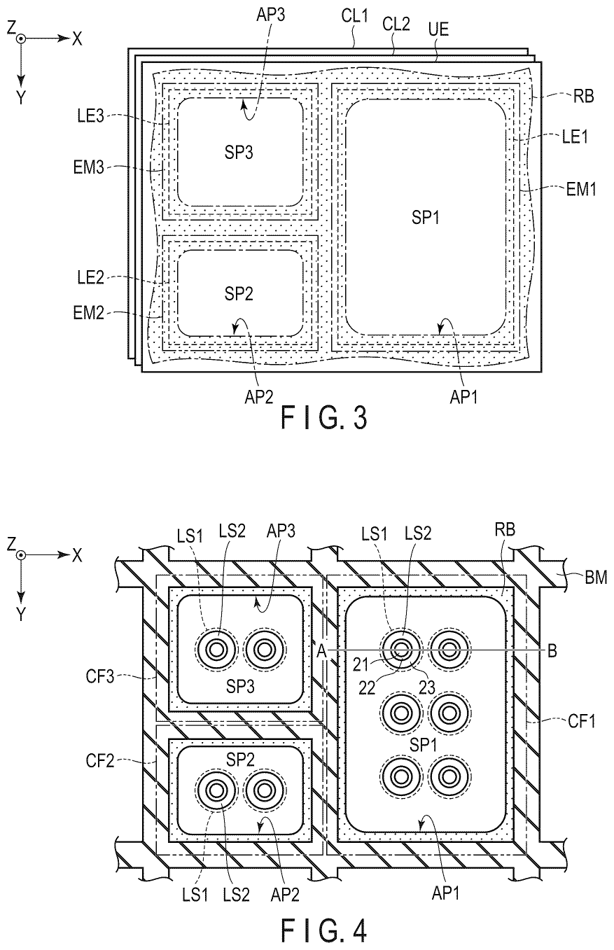

FIG. 3 is a diagram showing an example of the layout of subpixels SP1, SP2 and SP3.

In the example shown in the figure, subpixel SP1 and subpixel SP2 are arranged in the first direction X. Subpixel SP1 and subpixel SP3 are arranged in the first direction X. Subpixel SP2 and subpixel SP3 are arranged in the second direction Y.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 3. As another example of the layout, subpixels SP1, SP2 and SP3 may be arranged in order in the first direction X.

A rib RB indicated by dashed lines has apertures AP1, AP2 and AP3 in subpixels SP1, SP2 and SP3, respectively. In the example shown in the figure, the areas of the apertures AP1, AP2 and AP3 are different from each other. Specifically, the area of the aperture AP3 is less than that of the aperture AP1, and the area of the aperture AP2 is less than that of the aperture AP3.

In subpixel SP1, both the lower electrode LE1 indicated by broken lines and the light emitting layer EM1 indicated by double chain lines overlap the aperture AP1 as seen in plan view. The lower electrode LE1 is electrically connected to the pixel circuit 1 (see FIG. 1) of subpixel SP1. The peripheral portion of each of the lower electrode LE1 and the light emitting layer EM1 overlaps the rib RB.

In subpixel SP2, both the lower electrode LE2 and the light emitting layer EM2 overlap the aperture AP2 as seen in plan view. The lower electrode LE2 is electrically connected to the pixel circuit 1 of subpixel SP2. The peripheral portion of each of the lower electrode LE2 and the light emitting layer EM2 overlaps the rib RB.

In subpixel SP3, both the lower electrode LE3 and the light emitting layer EM3 overlap the aperture AP3 as seen in plan view. The lower electrode LE3 is electrically connected to the pixel circuit 1 of subpixel SP3. The peripheral portion of each of the lower electrode LE3 and the light emitting layer EM3 overlaps the rib RB.

The lower electrodes LE1, LE2 and LE3 are spaced apart from each other. The light emitting layers EM1, EM2 and EM3 are spaced apart from each other. The common layer CL1, the common layer CL2 and the upper electrode UE overlap each of the apertures AP1, AP2 and AP3 and overlap the rib RB.

It should be noted that the outer shape of each of the apertures AP1, AP2 and AP3, the lower electrodes LE1, LE2 and LE3 and the light emitting layers EM1, EM2 and EM3 does not necessarily reflect the accurate shape.

FIG. 4 is a diagram showing an example of the layout of the color filters CF1, CF2 and CF3, first lenses LS1 and second lenses LS2. It should be noted that the illustrations of the lower electrode, organic layer, upper electrode, etc., constituting the display element of each subpixel are omitted in FIG. 4.

The color filters CF1, CF2 and CF3 are spaced apart from each other. A light-shielding layer BM overlaps the rib RB and is formed into a grating shape which surrounds the apertures AP1, AP2 and AP3.

In subpixel SP1, the color filter CF1 indicated by the double chain lines overlaps the aperture AP1 as seen in plan view. The peripheral portion of the color filter CF1 overlaps the rib RB and the light-shielding layer BM.

In subpixel SP2, the color filter CF2 overlaps the aperture AP2 as seen in plan view. The peripheral portion of the color filter CF2 overlaps the rib RB and the light-shielding layer BM.

In subpixel SP3, the color filter CF3 overlaps the aperture AP3 as seen in plan view. The peripheral portion of the color filter CF3 overlaps the rib RB and the light-shielding layer BM.

In each of subpixels SP1, SP2 and SP3, both the first lenses LS1 indicated by the broken lines and the second lenses LS2 indicated by the solid lines are surrounded by the rib RB as seen in plan view. In other words, in subpixel SP1, the first lenses LS1 and the second lenses LS2 overlap the aperture AP1, and further overlap the color filter CF1. In subpixel SP2, the first lenses LS1 and the second lenses LS2 overlap the aperture AP2, and further overlap the color filter CF2. In subpixel SP3, the first lenses LS1 and the second lenses LS2 overlap the aperture AP3, and further overlap the color filter CF3.

Each first lens LS1 is formed into a circular shape as seen in plan view. Each first lens LS1 is, for example, a single-layer body formed of a single material. In the example shown in the figure, all of the first lenses LS1 have the same diameter. At least one of the first lenses LS1 may have a diameter different from that of the other first lenses LS1.

Each second lens LS2 is formed into a circular shape as seen in plan view. Each second lens LS2 is a multilayer body consisting of at least two layers. In the example shown in the figure, each second lens LS2 has a first layer 21, a second layer 22 which covers the first layer 21, and a third layer 23 which covers the second layer 22. The first layer 21, the second layer 22 and the third layer 23 are formed of materials different from each other. The refractive index of each of the first layer 21, the second layer 22 and the third layer 23 is different from each other. The outer edge of the first layer 21, the outer edge of the second layer 22 and the outer edge of the third layer 23 are formed concentrically as seen in plan view. In the example shown in the figure, all of the second lenses LS2 have the same diameter. At least one of the second lenses LS2 may have a diameter different from that of the other second lenses LS2.

In the example shown in the figure, in each subpixel, the number of first lenses LS1 is equal to the number of second lenses LS2. It should be noted that the number of first lenses LS1 may be different from the number of second lenses LS2.

In the example shown in the figure, the diameter of each second lens LS2 is equal to that of each first lens LS1. It should be noted that the diameter of each second lens LS2 may be different from that of each first lens LS1.

In the example shown in the figure, each second lens LS2 overlaps a corresponding first lens LS1 as seen in plan view. Each second lens LS2 may be provided so as to deviate from a corresponding first lens LS1 as seen in plan view. However, each second lens LS2 should preferably overlap at least part of a corresponding first lens LS1.

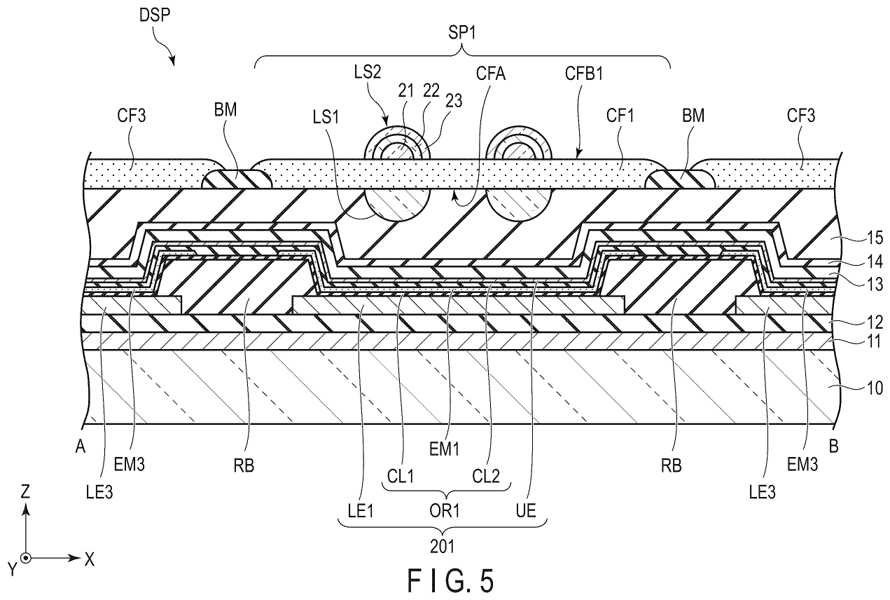

FIG. 5 is a cross-sectional view showing a configuration example of the display device DSP along the A-B line of FIG. 4. Here, this specification mainly explains the sectional structure of subpixel SP1.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 includes an organic insulating layer which planarizes the irregularities formed by the circuit layer 11.

The lower electrode LE1 of the display element 201 is provided on the insulating layer 12. The other lower electrodes LE2 and LE3 are also provided on the insulating layer 12. The lower electrode LE1 is, for example, a multilayer body including an oxide conductive layer formed of indium tin oxide (ITO) etc., and a metal layer formed of silver etc.

The rib RB is provided on the insulating layer 12. The rib RB covers the peripheral portion of the lower electrode LE1. The rib RB is formed of an organic material or an inorganic material.

The common layer CL1 is provided on the lower electrode LE1 and the rib RB. The light emitting layer EM1 is located immediately above the lower electrode LE1 and is provided on the common layer CL1. The common layer CL2 is provided on the light emitting layer EM1 and is provided on the common layer CL1 outside the light emitting layer EM1. These common layer CL1, light emitting layer EM1 and common layer CL2 constitute the organic layer OR1 as explained with reference to FIG. 2.

The upper electrode UE is provided on the common layer CL2. The upper electrode UE is formed of, for example, a metal material such as an alloy of magnesium and silver (MgAg).

A cap layer 13 is provided on the upper electrode UE. The cap layer 13 is a transparent multilayer body. The refractive indices of the layers constituting the cap layer 13 are different from each other. This cap layer 13 functions as an optical adjustment layer for adjusting the optical property of the light emitted from the light emitting layer EM1.

A sealing layer 14 is provided on the cap layer 13. The sealing layer 14 is formed of, for example, a transparent inorganic material such as silicon nitride (SiNx), silicon oxide (SiOx) or silicon oxynitride (SiON).

An insulating layer 15 is provided on the sealing layer 14. The insulating layer 15 is formed of a transparent organic material.

The color filter CF1 and the light-shielding layer BM are provided on the insulating layer 15. The color filter CF1 is provided immediately above the display element 201. The light-shielding layer BM is provided immediately above the rib RB. The peripheral portion of the color filter CF1 overlaps the light-shielding layer BM. This light-shielding layer BM absorbs external light and prevents undesired reflection of light.

The color filter CF1 has a first surface (lower surface) CFA which faces the insulating layer 15, and a second surface (upper surface) CFB on a side opposite to the first surface CFA.

The first lens LS1 is provided on the first surface CFA immediately above the lower electrode LE1 and is formed into a convex shape toward the display element 201. The first lens LS1 is covered with the insulating layer 15. In other words, the recess portion of the insulating layer 15 is filled with the first lens LS1. The first lens LS1 has a semicircular section as shown in the figure and has a circular outer edge as shown in FIG. 4. Thus, the first lens LS1 is formed into a hemispherical shape. This first lens LS1 is formed of a transparent organic material. The refractive index of the first lens LS1 is higher than that of the insulating layer 15.

The second lens LS2 is provided on the second surface CFB immediately above the lower electrode LE1 and is formed into a convex shape on a side opposite to the first lens LS1. In the example shown in the figure, the second lens LS2 is located immediately above the first lens LS1. The T first layer 21 of the second lens LS2 is formed into a hemispherical shape on the second surface CFB and has a first refractive index. The second layer 22 has substantially a constant thickness, covers the first layer 21, is in contact with the second surface CFB and has a second refractive index which is higher than the first refractive index. The third layer 23 has substantially a constant thickness, covers the second layer 22, is in contact with the second surface CFB and has a third refractive index which is higher than the second refractive index.

The first layer 21 is formed of a transparent organic material. For example, the first refractive index of the first layer 21 is less than or equal to approximately 1.4. Each of the second layer 22 and the third layer 23 is formed of a transparent inorganic material or a transparent organic material. For example, the third refractive index of the third layer 23 is greater than or equal to approximately 1.6. The second refractive index of the second layer 22 is greater than 1.4 and less than 1.6.

It should be noted that the second lens LS2 can consist of at least the first layer 21 and the second layer 22 and may be a multilayer body consisting of four or more layers. In any case, in the second lens LS2, the refractive index of the first layer 21 is the least, and the refractive index increases for each layer toward the external side relative to the first layer 21.

In this display element 201, when a potential difference is formed between the lower electrode LE1 and the upper electrode UE, the light emitting layer EM1 of the organic layer OR1 emits light. The light emitted from the light emitting layer EM1 passes through the cap layer 13, the sealing layer 14 and the insulating layer 15, is moderately converged by the first lens LS1, passes through the color filter CF1, and subsequently, moderately diverges through the second lens LS2.

In the configuration of providing the color filter CF1 above the display element 201 and providing the light-shielding layer BM which overlaps the peripheral portion of the color filter CF1, the transmittance of the light emitted from the light emitting layer EM1 is increased compared to a configuration in which an antireflective circular polarizer is provided. Thus, a high luminance can be obtained with low power, thereby elongating the life.

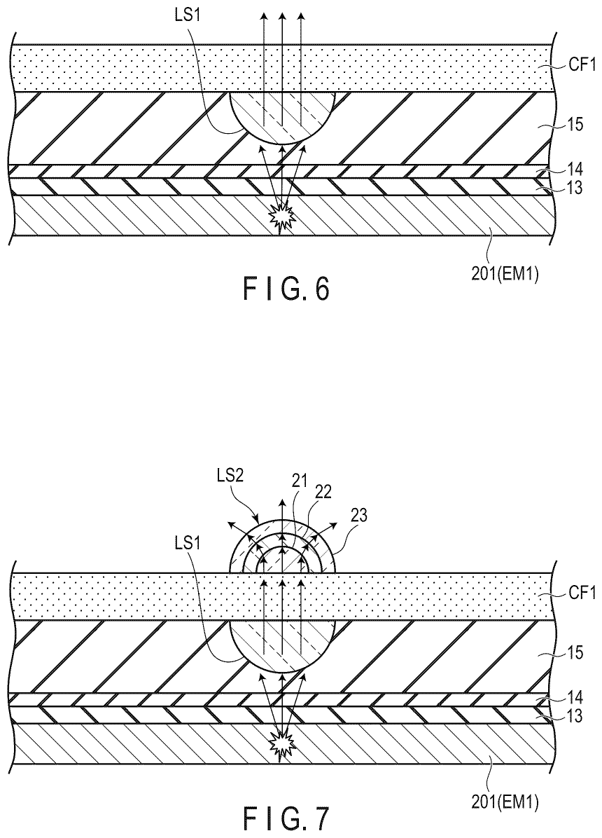

FIG. 6 is a diagram for explaining the effect of the first lens LS1.

The light emitted in the light emitting layer EM1 of the display element 201 is divergent light. Part of the light is trapped inside the display device.

To solve this problem, in the embodiment, the first lens LS1 having a convex shape toward the display element 201 is provided so as to be in contact with the insulating layer 15, and further, the refractive index of the first lens LS1 is higher than that of the insulating layer 15. Therefore, the light which reached the first lens LS1 from the display element 201 is refracted on the interface between the insulating layer 15 and the first lens LS1, is moderately converged, and is emitted in the normal direction of the display device. In this manner, the light trapped inside the display device is decreased, thereby improving the light extraction efficiency.

The inventor conducted a simulation by comparing the luminance of a comparative example which does not comprise any first lens LS1 with the luminance of the embodiment which comprises the first lenses LS1. The luminance obtained from the embodiment was higher than that obtained from the comparative example. In particular, it was confirmed that the luminance in the normal direction of the display device is approximately 1.8 times the luminance of the comparative example.

FIG. 7 is a diagram for explaining the effect of the second lens LS2.

As described above, the second lens LS2 is a multilayer body, and the refractive indices of the layers of the second lens LS2 are different from each other. Therefore, the light which enters the second lens LS2 from the color filter CF1 is refracted so as to diverge at the interface between the first layer 21 and the second layer 22, is refracted so as to diverge at the interface between the second layer 22 and the third layer 23 and is further refracted so as to diverge at the interface between the third layer 23 and air. Thus, the light which passed through the second lens LS2 diverges at a large angle relative to the normal of the display device.

The second lens LS2 is formed into a hemispherical shape. Therefore, in the second lens LS2, the light emission is not limited to a specific direction. Light can isotropically diverge over all directions in an X-Y plane.

Thus, even when the display device DSP is observed at a large observation angle relative to the normal, the light emitted from the display element 201 can be visually recognized. In addition, the light extraction efficiency is improved by the first lenses LS1, and further, light which is moderately converged enters the second lenses LS2. Thus, a viewing angle at which light having a high luminance can be visually recognized can be enlarged.

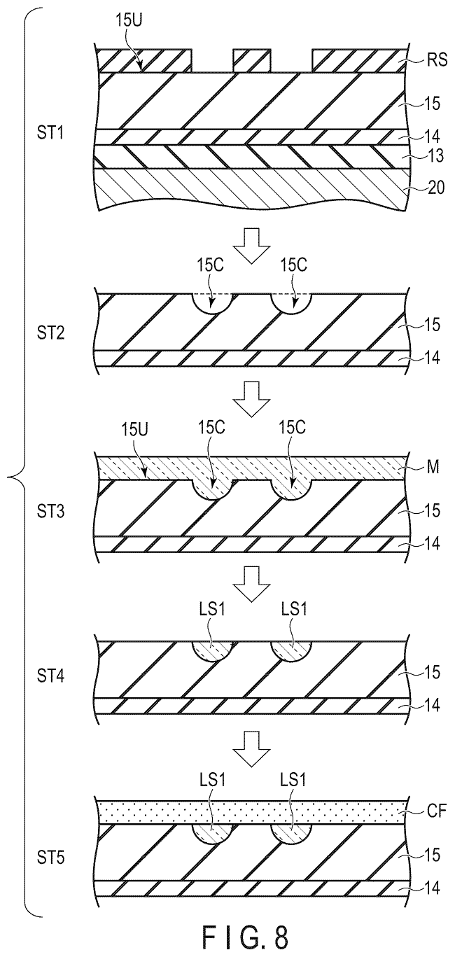

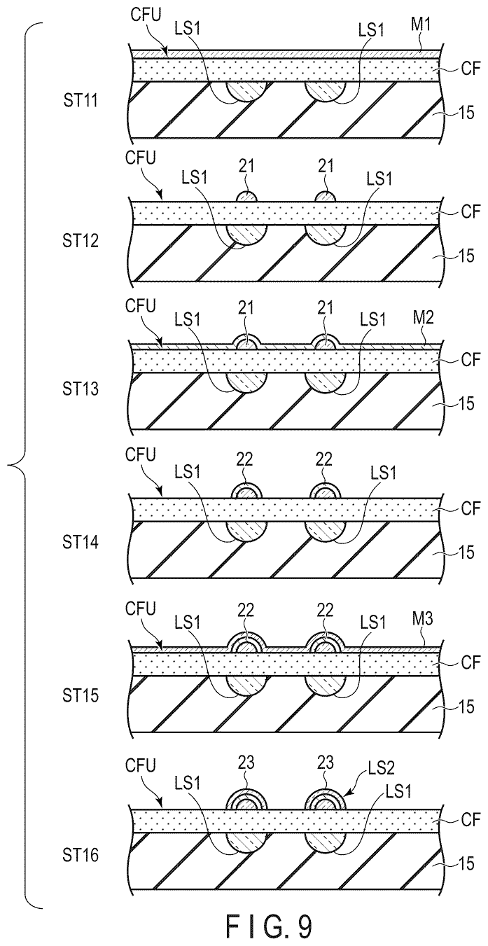

Now, this specification explains the manufacturing method of the display device DSP described above with reference to FIG. 8 and FIG. 9. Here, in particular, the manufacturing method of the first lenses LS1, a color filter and the second lenses LS2 is explained.

First, as shown in step ST1 of FIG. 8, the insulating layer 15 is formed above the display element 20 by using an organic material. Here, the display element 20 corresponds to the display element 201, 202 or 203 described above. Subsequently, a patterned resist RS is formed on the upper surface 15U of the insulating layer 15.

Subsequently, as shown in step ST2, the insulating layer 15 is partly removed by ashing using the resist RS as a mask, and thus, recess portions 15C are formed. Subsequently, the resist RS is removed.

Subsequently, as shown in step ST3, material M for forming the first lenses LS1 is applied to the upper surface 15U of the insulating layer 15, and the recess portions 15C are filled with material M. Material M is a material having a higher refractive index than the refractive index of the insulating layer 15, and is, for example, an organic material such as acrylic resin. As an example of acrylic resin, polymethyl methacrylate resin (PMMA) can be applied.

Subsequently, as shown in step ST4, material M overlapping the upper surface 15U is removed. By this process, the first lenses LS1 with which the recess portions 15C are filled are formed. It should be noted that material M overlapping the upper surface 15U may remain. The first lenses LS1 of subpixels SP1, SP2 and SP3 are formed at the same time.

Subsequently, as shown in step ST5, a color filter CF is formed on the first lenses LS1. Strictly, the light-shielding layer BM shown in FIG. 5 is formed before the formation of the color filter CF. As the color filter CF, the color filter CF1 of subpixel SP1, the color filter CF2 of subpixel SP2 and the color filter CF3 of subpixel SP3 are formed in order. It should be noted that the formation order of the color filters CF1, CF2 and CF3 is freely determined.

Subsequently, as shown in step ST11 of FIG. 9, material M1 for forming the first layer 21 of each second lens LS2 is applied to the upper surface CFU of the color filter CF. Here, the upper surface CFU corresponds to, for example, the second surface CFB of FIG. 5. Material M1 is a material having the first refractive index, and is, for example, an organic material such as fluorine resin or silicone resin. As an example of fluorine resin, polytetrafluoroethylene (PTFE) can be applied. As an example of silicone resin, polydimethyl siloxane (PDMS) can be applied.

Subsequently, as shown in step ST12, material M1 is patterned, and the reflowing of the remaining material M1 is performed as needed. By this process, the hemispherical first layers 21 are formed.

Subsequently, as shown in step ST13, the upper surface CFU and the first layers 21 are covered with material M2 for forming the second layer 22 of each second lens LS2. Material M2 is a material having the second refractive index higher than the first refractive index, and is, for example, an inorganic material such as silicon oxide (SiO₂) or an organic material such as PMMA. When material M2 is an inorganic material, material M2 is deposited on the upper surface CFU by, for example, chemical vapor deposition (CVD) or sputtering. When material M2 is an organic material, material M2 is applied to the upper surface CFU.

Subsequently, material M2 is patterned as shown in step ST14. By this process, the second layers 22 are formed.

Subsequently, as shown in step ST15, the upper surface CFU and the second layers 22 are covered with material M3 for forming the third layer 23 of each second lens LS2. Material M3 is a material having the third refractive index higher than the second refractive index, and is, for example, an inorganic material such as zirconium oxide (ZrO₂) or tantalum oxide (TaO₅) or an organic material such as epoxy resin. When material M3 is an inorganic material, material M3 is deposited on the upper surface CFU by, for example, CVD or sputtering. When material M3 is an organic material, material M3 is applied to the upper surface CFU.

Subsequently, material M3 is patterned as shown in step ST16. By this process, the third layers 23 are formed, and the second lenses LS2 are formed.

Now, this specification explains several other configuration examples. In each of the configuration examples described below, the first lenses LS1 and the second lenses LS2 in subpixel SP1 are explained. In figures corresponding to the configuration examples, the illustration of the display element is omitted.

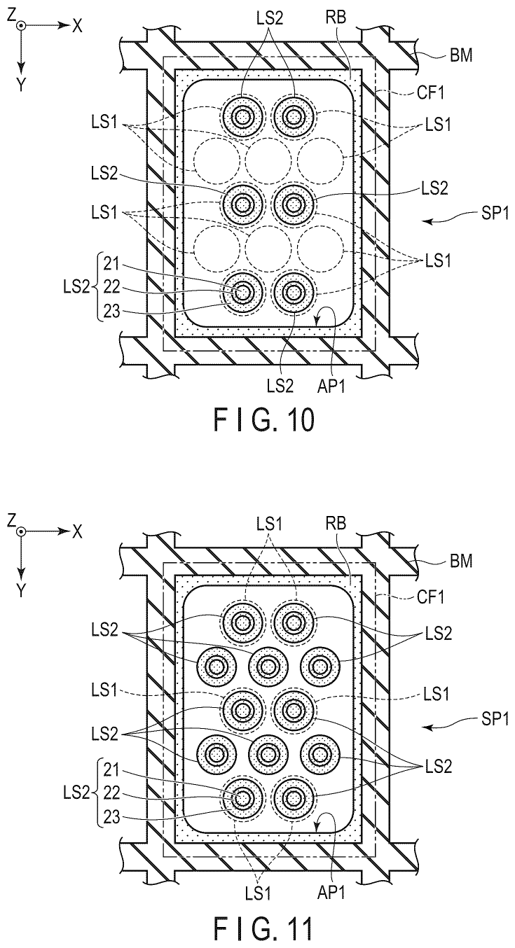

FIG. 10 is a diagram showing another example of the layout of the first lenses LS1 and the second lenses LS2.

The example shown in FIG. 10 is different from that shown in FIG. 4 in respect that the number of first lenses LS1 provided in subpixel SP1 is greater than the number of second lenses LS2. Since a large number of first lenses LS1 are provided, light which is trapped in the display device is further decreased, and the light extraction efficiency can be improved.

FIG. 11 is a diagram showing another example of the layout of the first lenses LS1 and the second lenses LS2.

The example shown in FIG. 11 is different from that shown in FIG. 4 in respect that the number of second lenses LS2 provided in subpixel SP1 is greater than the number of first lenses LS1. Since a large number of second lenses LS2 are provided, a wide viewing angle can be realized.

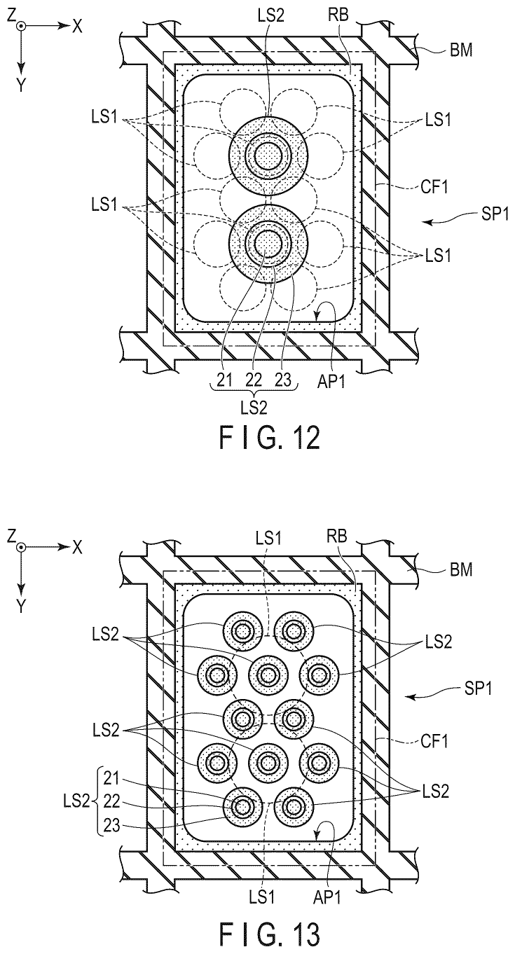

FIG. 12 is a diagram showing another example of the layout of the first lenses LS1 and the second lenses LS2.

The example shown in FIG. 12 is different from that shown in FIG. 4 in respect that the number of first lenses LS1 provided in subpixel SP1 is greater than the number of second lenses LS2, and the diameter of each second lens LS2 is greater than that of each first lens LS1. A plurality of first lenses LS1 overlap a single second lens LS2 as seen in plan view. Even in this configuration example, effects similar to those of the above descriptions can be obtained.

FIG. 13 is a diagram showing another example of the layout of the first lenses LS1 and the second lenses LS2.

The example shown in FIG. 13 is different from that shown in FIG. 4 in respect that the number of second lenses LS2 provided in subpixel SP1 is greater than the number of first lenses LS1, and the diameter of each first lens LS1 is greater than that of each second lens LS2. A plurality of second lenses LS2 overlap a single first lens LS1 as seen in plan view. Even in this configuration example, effects similar to those of the above descriptions can be obtained.

As explained above, the embodiments can provide a display device in which the light extraction efficiency is improved and the viewing angle can be broadened, and a manufacturing method thereof.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
a lower electrode provided above the substrate;
an organic layer provided on the lower electrode and including a light emitting layer;
an upper electrode provided on the organic layer;
an insulating layer provided above the upper electrode;
a color filter having a first surface which faces the insulating layer, and a second surface on a side opposite to the first surface;
a first lens provided on the first surface immediately above the lower electrode, formed into a convex shape and covered with the insulating layer; and
a second lens provided on the second surface immediately above the lower electrode and formed into a convex shape, wherein
the second lens comprises at least a first layer having a first refractive index and formed into a hemispherical shape, and a second layer having a second refractive index higher than the first refractive index and covering the first layer.

2. The display device of claim 1, wherein
the second lens further comprises a third layer having a third refractive index higher than the second refractive index and covering the second layer.

3. The display device of claim 2, wherein
an outer edge of the first layer, an outer edge of the second layer and an outer edge of the third layer are formed concentrically in plan view.

4. The display device of claim 2, wherein
the first layer is formed of an organic material, and
each of the second layer and the third layer is formed of an inorganic material or an organic material.

5. The display device of claim 1, wherein
the second lens overlaps at least part of the first lens in plan view.

6. The display device of claim 1, further comprising:
a cap layer provided on the upper electrode; and
a sealing layer provided on the cap layer and formed of an inorganic material, wherein
the insulating layer is provided on the sealing layer and is formed of an organic material, and
the first lens is formed of an organic material having a refractive index higher than a refractive index of the insulating layer.

7. The display device of claim 1, further comprising a rib which covers a peripheral portion of the lower electrode, wherein
the first lens and the second lens are surrounded by the rib in plan view.

8. The display device of claim 7, wherein
first lenses and second lenses are surrounded by the rib in plan view, and
the number of the first lenses is equal to the number of the second lenses.

9. The display device of claim 7, wherein
first lenses and second lenses are surrounded by the rib in plan view, and
the number of the first lenses is different from the number of the second lenses.

10. The display device of claim 1, further comprising a rib which covers a peripheral portion of the lower electrode, wherein
first lenses are surrounded by the rib in plan view and overlap the single second lens.

11. The display device of claim 1, further comprising a rib which covers a peripheral portion of the lower electrode, wherein
second lenses are surrounded by the rib in plan view and overlap the single first lens.

12. A manufacturing method of a display device, comprising:
forming an insulating layer above a display element by using an organic material;
forming a patterned resist on the insulating layer;
forming a recess portion by removing part of the insulating layer using the resist as a mask;
forming a first lens with which the recess portion is filled;
forming a color filter on the first lens; and
forming a second lens having a convex shape on the color filter, wherein
the forming the second lens includes at least:
forming a hemispherical first layer by using a material having a first refractive index; and
forming a second layer which covers the first layer by using a material having a second refractive index higher than the first refractive index.

13. The manufacturing method of claim 12, wherein
the forming the second lens further includes forming a third layer which covers the second layer by using a material having a third refractive index higher than the second refractive index.

14. The manufacturing method of claim 13, wherein
the first layer is formed of an organic material, and
each of the second layer and the third layer is formed of an inorganic material or an organic material.

15. The manufacturing method of claim 12, wherein
the first lens is formed of an organic material having a refractive index higher than a refractive index of the insulating layer.
